(19) United States
(12) Patent Application Publication
(10) Pub. No.: US 2026/0122944 A1
(43) Pub. Date: Apr. 30, 2026

(54) METHOD FOR MAKING LATERALLY-DIFFUSED METAL-OXIDE SEMICONDUCTOR (LDMOS) DEVICES INCLUDING SUPERLATTICE TRENCH LINER

(71) Applicant: ATOMERA INCORPORATED, LOS GATOS, CA (US)

(72) Inventors: HIDEKI TAKEUCHI, SAN JOSE, CA (US); ROBERT J. MEARS, WELLESLEY, MA (US); SHUYI LI, LOS GATOS, CA (US)

(21) Appl. No.: 19/371,349

(22) Filed: Oct. 28, 2025

Related U.S. Application Data
(60) Provisional application No. 63/713,352, filed on Oct. 29, 2024.

(51) Int. Cl. H10D 30/01; H10D 30/65; H10D 62/10; H10D 62/60; H10D 62/815

(52) U.S. Cl. CPC H10D 30/0281; H10D 62/116; H10D 62/124; H10D 62/60; H10D 62/8162; H10D 30/65

(57) ABSTRACT

A method for making an LDMOS device may include forming a trench in a semiconductor layer, and forming a superlattice liner in the trench. The superlattice liner may include stacked groups of layers, with each group of layers comprising stacked base semiconductor monolayers defining a base semiconductor portion and at least one non-semiconductor monolayer, and each at least one non-semiconductor monolayer of each group of layers being constrained within a crystal lattice of adjacent base semiconductor portions. The method may further include forming a drift region in the semiconductor layer surrounding the trench, forming a shallow trench isolation (STI) region within the trench and separated from the drift region by the superlattice liner, forming spaced-apart source and drain regions in the semiconductor layer on opposite sides of the trench, and forming a gate on the semiconductor layer between the source and drain regions.

### RELATED APPLICATIONS

This application claims the benefit of U.S. App. No. 63/713,352 filed Oct. 29, 2024, which is hereby incorporated herein in its entirety by reference.

### TECHNICAL FIELD

The present disclosure generally relates to semiconductor devices, and, more particularly, to metal oxide semiconductor field effect transistor (MOSFET) devices and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO₂/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making a laterally-diffused metal-oxide semiconductor (LDMOS) device may include forming a trench in a semiconductor layer, and forming a superlattice liner in the trench. The superlattice liner may include a plurality of stacked groups of layers, with each group of layers comprising a plurality of stacked base semiconductor monolayers defining a base semiconductor portion and at least one non-semiconductor monolayer, and each at least one non-semiconductor monolayer of each group of layers being constrained within a crystal lattice of adjacent base semiconductor portions. The method may further include forming a drift region in the semiconductor layer surrounding the trench, forming a shallow trench isolation (STI) region within the trench and separated from the drift region by the superlattice liner, forming spaced-apart source and drain regions in the semiconductor layer on opposite sides of the trench, and forming a gate on the semiconductor layer between the source and drain regions.

The drift region may comprise a first conductivity type dopant, and the superlattice liner may have a higher concentration of the first conductivity type dopant than adjacent portions of the drift region. The method may further include forming a body region within the semiconductor layer surrounding the source region. More particularly, the drift region may have a first conductivity type dopant, and the body region may have a second conductivity type dopant opposite the first conductivity type. The method may further include forming a body contact in the semiconductor layer within the body region.

Forming the drain region may comprise forming the drain region within the drift region. Further, the method may include forming a well region in the semiconductor layer beneath the drift region. By way of example, the base semiconductor monolayers may comprise silicon, and the at least one non-semiconductor monolayer may comprise oxygen.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a schematic cross-sectional diagram of an LDMOS device including a superlattice trench liner in accordance with an example embodiment.

FIG. 5 is a graph illustrating phosphorous concentration adjacent the superlattice trench liner in the device of FIG. 4.

FIG. 6 is a flow diagram illustrating a method for making the LDMOS in accordance with an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers and that this thereby leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface may more effectively confine free carriers (electrons or holes) in the silicon, and thus improve the mobility of these carriers due to electric fields applied parallel to the interface, as is standard practice in field-effect-transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as will be discussed further below.

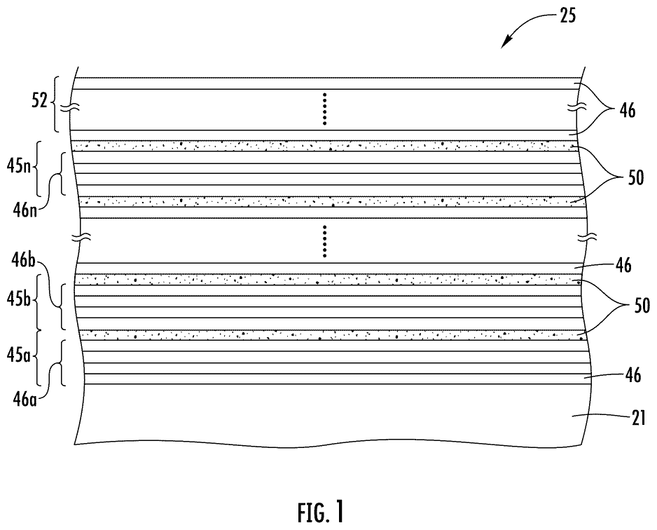

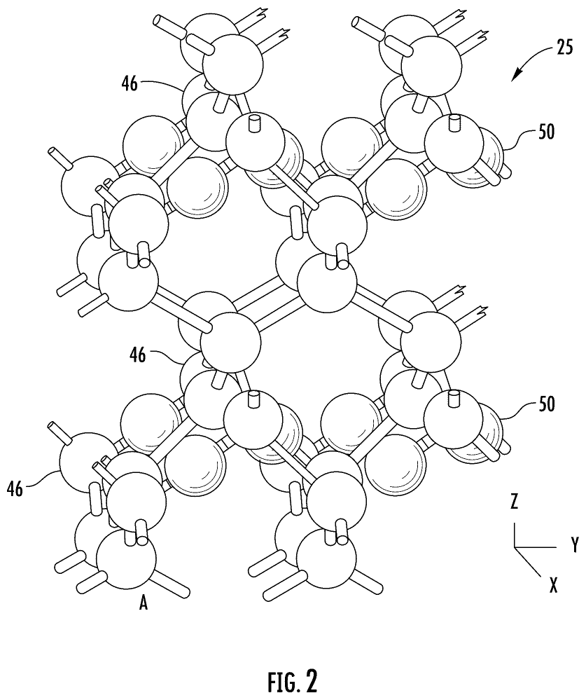

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that non-semiconductor monolayers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present embodiments, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the embodiments may be readily adopted and implemented, as will be appreciated by those skilled in the art.

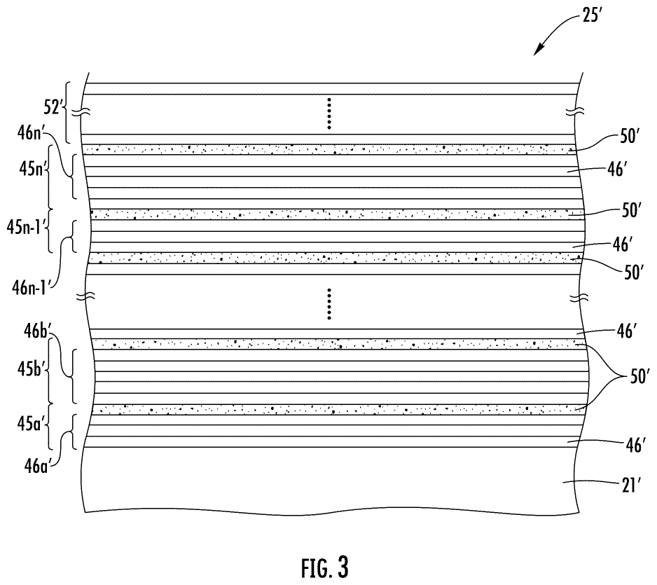

Referring now additionally to FIG. 3, another embodiment of a superlattice 25′ in accordance with the embodiments having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

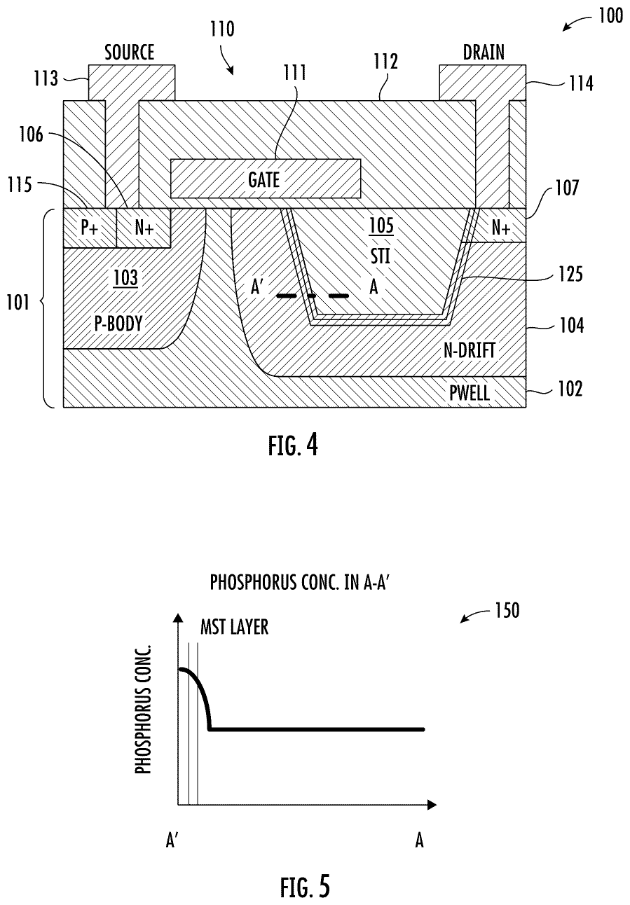

Turning now to FIG. 4, the above-described MST films may be incorporated within a laterally-diffused metal-oxide semiconductor (LDMOS) device 100 to provide certain technical advantages. By way of background, LDMOS devices used for applications such as >30V power switching typically implement shallow trench isolation (STI) regions in the drift region of the device to help retain BV_{DSS}. This is done to improve drift sheet resistance in such LDMOS devices.

The LDMOS device 100 illustratively includes a substrate or semiconductor layer 101 having a PWELL 102, as well as P-body and N-drift regions 103, 104 in the PWELL. The STI region 105 is within the N-drift region 104, and a trench in which the STI region is formed is lined with an MST superlattice film 125. That is, the MST superlattice film 125 separates the N-drift region 104 from the STI region 105. A source region 106 is within the P-body region 103, and a drain region 107 is within the N-drift region 104 at the top of the semiconductor layer 101. A gate 110 including a gate electrode 111 and a gate dielectric 112 is positioned on the semiconductor layer 101 between the source and drain regions 106, 107, and each of the source and drain regions has a respective source and drain contact 113, 114. A body contact region 115 is also within the P-body region 103. The MST epi process discussed further above may be performed after the STI etch, but prior to formation of the STI region 105.

By way of example, the present embodiment employs a tilted or slanted phosphorous ion implantation to form the N-drift region 104. The MST superlattice layer 125 advantageously piles up phosphorus at the STI/Si boundaries of the N-drift region 104. The tilted implant also advantageously helps increase phosphorus concentrations at the STI region 105 sidewall. The result is that R_{DSON} is improved via higher concentration phosphorus in the electron conduction path. This result may be seen in the phosphorous concentration graph 150 of FIG. 5. Here a simulated result is shown for an example implementation of the LDMOS device 100, in which phosphorous pile-up concentration is represented along the line A′-A starting (on the left hand side) in the N-drift region 104 and ending (on the right hand side) in the STI region 105. This advantageously provides enhanced sheet resistance reduction in the electron path, as will be appreciated by those skilled in the art.

It will further be appreciated that the conductivity types for the N and P regions discussed above may be reversed in some embodiments, and a different dopant (e.g., boron) may be used for a P-drift region in such embodiments.

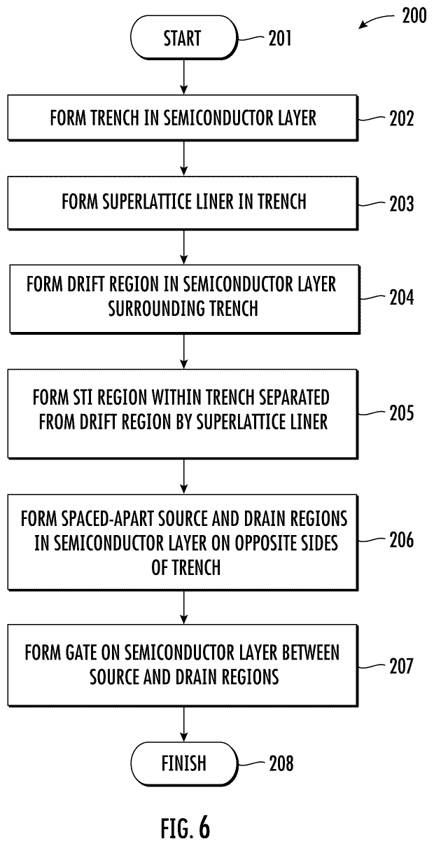

Turning to the flow diagram 200 of FIG. 6, a method of fabricating or making the LDMOS device 100 is now described. Beginning at Block 201, the method illustratively includes forming a trench in the semiconductor layer 101 (Block 202), and forming a superlattice liner 125 in the trench (Block 203), as discussed further above. The method further illustratively includes forming the N-drift region 104 in the semiconductor layer 101 surrounding the trench (Block 204), forming the STI region 105 within the trench and separated from the drift region by the superlattice liner 125 (Block 205), forming spaced-apart source and drain regions 106, 107 in the semiconductor layer on opposite sides of the trench (Block 206), and forming a gate 110 on the semiconductor layer between the source and drain regions (Block 207). The method of FIG. 6 illustratively concludes at Block 208. It should be noted that in different embodiments various steps may be performed in a different order than the example implementation shown. For example, the N-drift region 104 implant may occur before or after the MST superlattice layer 125 formation. Moreover, other semiconductor process steps may also be performed (e.g., body contact region 115 formation, source/drain contacts 113, 114 formation, etc.), as will be appreciated by those skilled in the art.

Many modifications and other embodiments will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. A method for making a laterally-diffused metal-oxide semiconductor (LDMOS) device comprising:
forming a trench in a semiconductor layer;
forming a superlattice liner in the trench, the superlattice liner comprising a plurality of stacked groups of layers, each group of layers comprising a plurality of stacked base semiconductor monolayers defining a base semiconductor portion and at least one non-semiconductor monolayer, with each at least one non-semiconductor monolayer of each group of layers being constrained within a crystal lattice of adjacent base semiconductor portions;
forming a drift region in the semiconductor layer surrounding the trench;
forming a shallow trench isolation (STI) region within the trench and separated from the drift region by the superlattice liner;
forming spaced-apart source and drain regions in the semiconductor layer on opposite sides of the trench; and
forming a gate on the semiconductor layer between the source and drain regions.

2. The method of claim 1 wherein the drift region comprises a first conductivity type dopant, and wherein the superlattice liner has a higher concentration of the first conductivity type dopant than adjacent portions of the drift region.

3. The method of claim 1 further comprising forming a body region within the semiconductor layer surrounding the source region.

4. The method of claim 3 wherein the drift region has a first conductivity type dopant, and the body region has a second conductivity type dopant opposite the first conductivity type.

5. The method of claim 3 further comprising forming a body contact in the semiconductor layer within the body region.

6. The method of claim 1 wherein forming the drain region comprises forming the drain region within the drift region.

7. The method of claim 1 further comprising forming a well region in the semiconductor layer beneath the drift region.

8. The method of claim 1 wherein the base semiconductor monolayers comprise silicon.

9. The method of claim 1 wherein the at least one non-semiconductor monolayer comprises oxygen.

10. A method for making a laterally-diffused metal-oxide semiconductor (LDMOS) device comprising:
forming a trench in a semiconductor layer;
forming a superlattice liner in the trench, the superlattice liner comprising a plurality of stacked groups of layers, each group of layers comprising a plurality of stacked base semiconductor monolayers defining a base semiconductor portion and at least one non-semiconductor monolayer, with each at least one non-semiconductor monolayer of each group of layers being constrained within a crystal lattice of adjacent base semiconductor portions;
forming a drift region in the semiconductor layer surrounding the trench, the drift region comprising a first conductivity type dopant, and the superlattice liner having a higher concentration of the first conductivity type dopant than adjacent portions of the drift region;
forming a shallow trench isolation (STI) region within the trench and separated from drift region by the superlattice liner;
forming a body region within the semiconductor layer;
forming spaced-apart source and drain regions in the semiconductor layer on opposite sides of the trench, with the source region within the body region; and
forming a gate on the semiconductor layer between the source and drain regions.

11. The method of claim 10 wherein the drift region has a first conductivity type dopant, and the body region has a second conductivity type dopant opposite the first conductivity type.

12. The method of claim 10 further comprising forming a body contact in the semiconductor layer within the body region.

13. The method of claim 10 wherein the drain region is within the drift region.

14. The method of claim 10 further comprising forming a well region in the semiconductor layer beneath the drift region.

15. A method for making a laterally-diffused metal-oxide semiconductor (LDMOS) device comprising:
a semiconductor layer having a trench therein;
a superlattice liner in the trench, the superlattice liner comprising a plurality of stacked groups of layers, each group of layers comprising a plurality of stacked base silicon monolayers defining a base silicon portion and at least one oxygen monolayer, with each at least one oxygen monolayer of each group of layers being constrained within a crystal lattice of adjacent base silicon portions;
a shallow trench isolation (STI) region within the trench;
spaced-apart source and drain regions in the semiconductor layer on opposite sides of the trench;
a gate on the semiconductor layer between the source and drain regions; and
a drift region in the semiconductor layer surrounding the trench and separated from the STI region by the superlattice liner.

16. The method of claim 15 wherein the drift region comprises a first conductivity type dopant, and wherein the superlattice liner has a higher concentration of the first conductivity type dopant than adjacent portions of the drift region.

17. The method of claim 15 further comprising forming a body region within the semiconductor layer surrounding the source region.

18. The method of claim 17 wherein the drift region has a first conductivity type dopant, and the body region has a second conductivity type dopant opposite the first conductivity type.

19. The method of claim 15 wherein the drain region is within the drift region.

20. The method of claim 15 further comprising forming a well region in the semiconductor layer beneath the drift region.
